(19) United States
(12) Patent Application Publication
(10) Pub. No.: US 2014/0090871 A1
(43) Pub. Date: Apr. 3, 2014

(54) GRAPHENE HYBRID STRUCTURES FOR TRANSPARENT CONDUCTIVE ELECTRODES

(71) Applicant: BLUESTONE GLOBAL TECH LIMITED, Wappingers Falls, NY (US)

(72) Inventors: Xin Zhao, Wappingers Falls, NY (US); Xuesong Li, Wappingers Falls, NY (US)

(73) Assignee: BLUESTONE GLOBAL TECH LIMITED, Wappingers Falls, NY (US)

(21) Appl. No.: 13/633,145

(22) Filed: Oct. 2, 2012

(51) Int. Cl. H01B 5/00; H01R 43/00

(52) U.S. Cl. 174/126.2; 29/885

(57) ABSTRACT

Aspects of the invention are directed to an electrode for use in an electronic device. The electrode comprises a plurality of nanostructures and a passivating film. Each nanostructure in the plurality of nanostructures contacts or is fused to one or more other nanostructures in the plurality of nanostructures. The passivating film at least partially covers the plurality of nanostructures and comprises one or more layers of graphene.

### FIELD OF THE INVENTION

The present invention relates generally to electronic devices, and, more particularly, to graphene-based transparent conductive electrodes for use in optoelectronic devices and the like.

### BACKGROUND OF THE INVENTION

Transparent conductive electrodes (hereinafter just “transparent electrodes”) are key elements for optoelectronic devices such as flat panel displays, touch panels, and light-emitting diodes. Traditionally, indium tin oxide (ITO) has been used for transparent electrodes in optoelectronic devices because of ITO's ability to provide low sheet resistances while maintaining high optical transmittances. Nevertheless, ITO has several disadvantages. Indium is relatively scarce and, as a result, ITO is expensive. Moreover, ITO is quite brittle, which makes it unsuitable for use in applications requiring that the transparent electrode be flexible. ITO is, for example, not well suited for use in roll-to-roll-processed photovoltaics and organic light-emitting diodes.

Efforts to find a replacement for ITO for use in transparent electrodes have recently focused on carbon-based nanostructures (e.g., carbon nanotubes and graphene) and metal-based nanostructures (silver and copper nanofibers). Information relevant to efforts to implement a transparent electrode with copper nanofibers can be found in, for example, U.S. Patent Publication No. 2012/0061124 to Cui et al., entitled “Electrodes with Electrospun Fibers,” which is not admitted as prior art by its discussion herein. In this reference, an electrode comprising a random network of electrospun copper nanofibers was reported as achieving a sheet resistance of 200 Ω/sq (ohms per square) while displaying a transmittance of about 96% in the visible and near infrared spectrum (i.e., 300-1,100 nanometers (nm)). Moreover, additional copper-nanofiber-based electrodes were reported as achieving a sheet resistance of 50 Ω/sq at about 90% transmittance as well as a sheet resistance of 12 Ω/sq at about 80% transmittance. In so doing, the copper-nanofiber-based electrodes showed better performance than commercial ITO electrodes according to a figure of merit proportional to transmittance divided by sheet resistance. In addition, the new copper-nanofiber-based electrodes demonstrated a relatively flat transmittance curve between 300 nm and 1,100 nm, while ITO-based electrodes tended to show a bent transmittance curve over the same spectrum range with a peak at around 500 nm. During all of this, the new carbon-nanofiber-based electrodes showed flexibility and stretchability properties well suited to flexible optoeletronic devices.

Nevertheless, despite the promise of transparent electrodes based on networks of metallic nanostructures, there remain several issues that need to be addressed. Metallic nanostructures, particularly those comprising copper, are very susceptible to oxidation when exposed to oxygen or moisture. Thick surface oxide layers on thin nanowires may, in turn, drastically degrade the electrical conductivity of these nanostructures. As a result, there is a need for new transparent electrode designs that can benefit from the use of metallic nanostructures while being resistant to long term environmental degradation.

### SUMMARY OF THE INVENTION

Embodiments of the present invention address the above-identified needs by providing transparent electrodes that benefit from the use of networks of highly conductive nanostructures while being resistant to long term physical and chemical degradation.

Aspects of the invention are directed to an electrode for use in an electronic device. The electrode comprises a plurality of nanostructures and a passivating film. Each nanostructure in the plurality of nanostructures contacts or is fused to one or more other nanostructures in the plurality of nanostructures. The passivating film at least partially covers the plurality of nanostructures and comprises one or more layers of graphene.

Additional aspects of the invention are directed to a method of forming an electrode. The method starts by forming a plurality of nanostructures. Each nanostructure in the plurality of nanostructures contacts or is fused to one or more other nanostructures in the plurality of nanostructures. A passivating layer is deposited on the plurality of nanostructures. The passivating film comprises one or more layers of graphene.

### BRIEF DESCRIPTION OF THE DRAWINGS

These and other features, aspects, and advantages of the present invention will become better understood with regard to the following description, appended claims, and accompanying drawings where:

FIG. 1 shows a perspective view of a portion of a transparent electrode on a substrate, in accordance with an illustrative embodiment of the invention;

FIG. 2 shows a sectional view of a passivated nanostructure in the FIG. 1 transparent electrode;

FIG. 3 shows a flow diagram of a method in accordance with an illustrative embodiment of the invention for forming the FIG. 1 transparent electrode;

FIGS. 4A and 4B show top elevational views of a disordered network of conductive nanostructures before and after passivation, respectively, in accordance with an illustrative embodiment of the invention;

FIGS. 5A and 5B show top elevational views of a disordered network of fused conductive nanostructures before and after passivation, respectively, in accordance with an illustrative embodiment of the invention;

FIGS. 6A and 6B show top elevational views of an ordered network of fused conductive nanostructures before and after passivation, respectively, in accordance with an illustrative embodiment of the invention;

FIG. 7 shows a sectional view of an organic photovoltaic device in accordance with an illustrative embodiment of the invention; and

FIG. 8 shows a sectional view of an organic light emitting diode device in accordance with an illustrative embodiment of the invention.

### DETAILED DESCRIPTION OF THE INVENTION

The present invention will be described with reference to illustrative embodiments. For this reason, numerous modifications can be made to these embodiments and the results will still come within the scope of the invention. No limitations with respect to the specific embodiments described herein are intended or should be inferred.

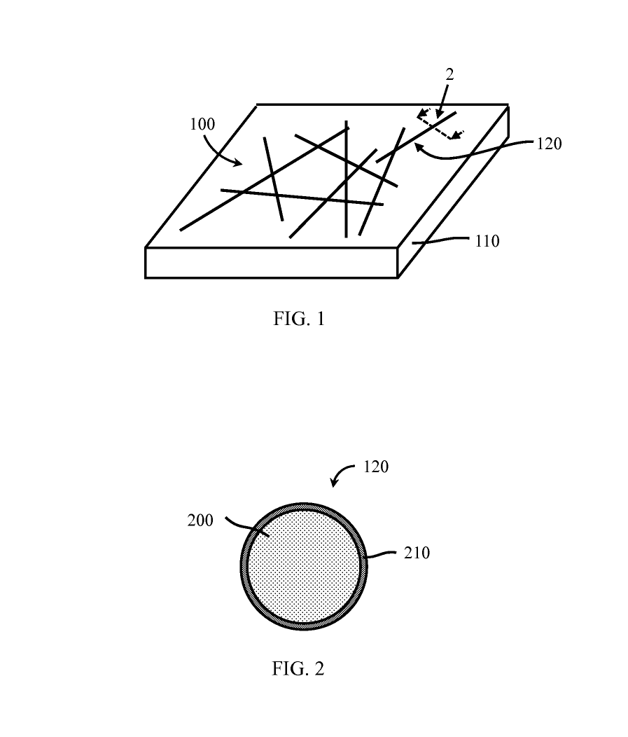

FIG. 1 shows a perspective view of a portion of a transparent electrode 100 on a substrate 110, in accordance with an illustrative embodiment of the invention. In this embodiment, the transparent electrode 100 comprises a randomly arranged (i.e., substantially disordered) plurality of passivated nanostructures 120 with each passivated nanostructure 120 contacting one or more other passivated nanostructures 120 in the plurality of passivated nanostructures 120. In so doing, the passivated nanostructures 120 create an interconnected network. The passivated nanostructures 120 themselves comprise two components. FIG. 2 shows a sectional view of a representative one of the passivated nanostructures 120 in the transparent electrode 100 along the plane indicated in FIG. 1. Each of the passivated nanostructures 120 comprises a respective conductive nanostructure 200 coated by a passivating film 210. The passivating film 210 is substantially continuous over all the conductive nanostructures 200 in the transparent electrode 100.

Each of the conductive nanostructures 200 preferably comprises a highly electrically conductive material such as, but not limited to, copper or silver. For purposes of this description, it will be assumed that the conductive nanostructures 200 comprise copper formed into “one-dimensional” cylindrical nanofibers, although conductive nanostructures with different morphologies (e.g., pills, rods) are also contemplated and would fall within the scope of the invention. The passivating film 210 comprises one or more layers of graphene. The passivating film 210 may therefore consist of only one layer of graphene, or may consist of two or more layers of graphene, as required by the application.

Formulated in this manner, the passivated nanostructures 120 create a transparent electrode 100 well suited to a diverse variety of optoelectronic applications. The interconnected network of passivated nanostructures 120 present a highly electrically conductive percolating network that has little overall density to interfere with light transmission. At the same time, the conductive nanostructures 200 are entirely encapsulated by one or more continuous layers of graphene. Graphene is largely impermeable to gas and ion diffusion, is lightweight, is characterized by excellent chemical and mechanical stability, is flexible, and is itself highly electrically conductive. The passivating film 210 thereby protects the conductive nanostructures 200 from chemical and physical degradation (e.g., corrosion, compaction, fragmentation) that may result from environmental exposure as well as from device processing.

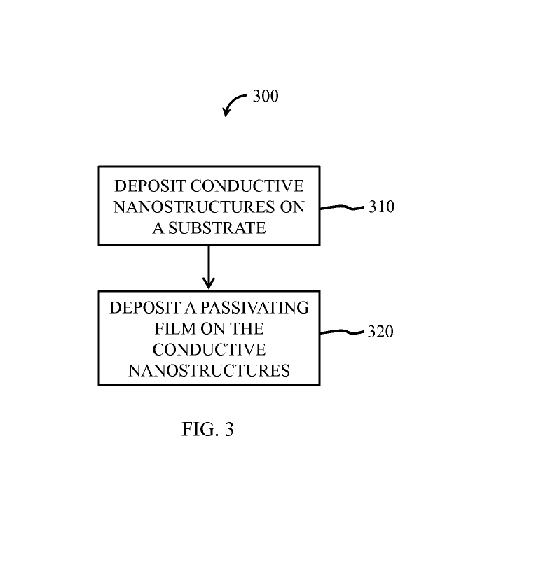

FIG. 3 shows a flow diagram of a method 300 in accordance with an illustrative embodiment of the invention for forming a transparent electrode similar to the transparent electrode 100. Step 310 in the method 300 comprises depositing conductive nanostructures, in this particular embodiment, copper nanofibers, on a substrate.

There are wide variety of approaches to forming conductive nanostructures such as copper nanofibers which will already be familiar to one having ordinary skill in the nanomaterials arts. These processing methods include, but are not limited to: solution-phase processing, electrospinning, and patterning. These methods and others are variously described in, for example: Hu et al., “Metal Nanogrids, Nanowires, and Nanofibers for Transparent Electrodes,” MRS Bulletin, October 2011, pp. 760-765, Vol. 36, Materials Research Society, USA; C.S.S.R. Kumar, Metallic Nanomaterials Vol. 1, John Wiley & Sons, 2009; International (Patent Application) Publication No. WO 2012/060776 to National University of Singapore, entitled “Metal Nanowires, Nanomesh and a Method of Fabrication”; U.S. Patent Publication No. 2012/0061124 to Cui et al., entitled “Electrodes with Electrospun Fibers”; and U.S. Patent Publication No. 2009/0046362 to Guo et al., entitled “Roll to Roll Nanoimprint Lithography,” which are all hereby incorporated by reference herein. Any method of forming the conductive nanostructures would ultimately fall within the scope of the invention.

Copper nanofibers may, for example, be formed using solution-phase processing. In one or more non-limiting embodiments of the present invention, as just one example, an aqueous solution of 20-30 milliliters (ml) of sodium hydroxide (NaOH; 3.5-15 Molar (M)) and 0.5-1.0 mL of cupric nitrate (Cu(NO₃)₂; 0.10 M) are placed into a glass reactor. Varying amounts of ethylenediamine (EDA; C₂H₄(NH₂)₂; 0.050-2.0 mL; 99 weight percent (wt %)) and hydrazine (N₂H₄; 0.020-1.0 mL; 35 wt %) are then added to the glass reactor sequentially, followed by a thorough mixing of all reagents. The reactor is subsequently placed in a water bath with a temperature between 25-100° C. for 15 minutes to 15 hours. The resultant copper nanofibers are washed and harvested with centrifugation-redispersion cycles and stored in a water-hydrazine solution to prevent oxidation.

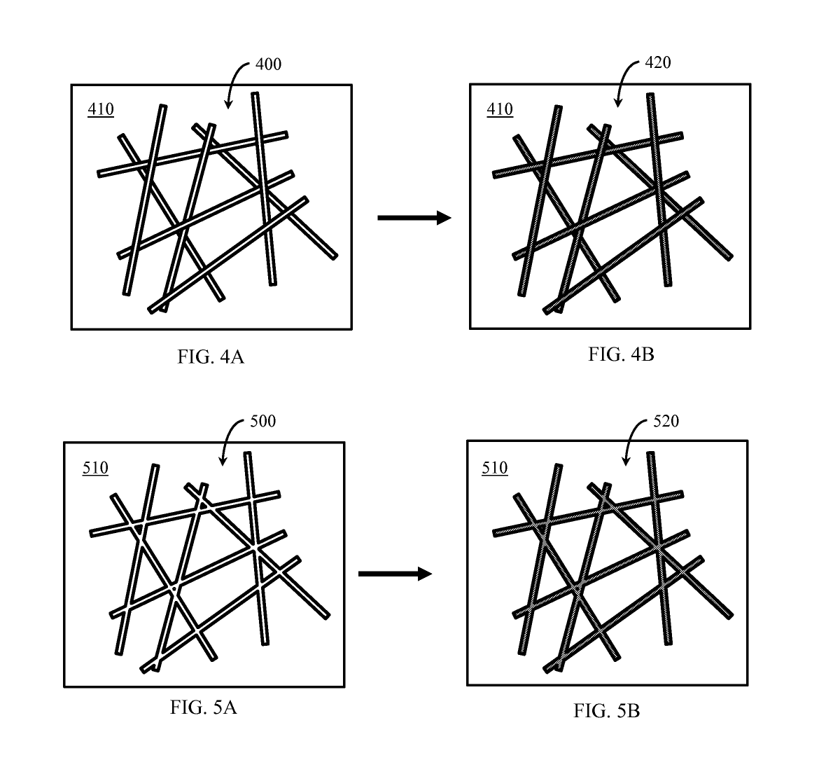

Once the liquid suspension of copper nanofibers is formed, it may be deposited on a suitable substrate (e.g., glass, plastic, or any other translucent material) by any one of a number of wet deposition methods. These include, but are not limited to, inkjet printing, spray coating, dip coating, and spin coating. FIG. 4A shows a top elevational view of an illustrative network of conductive nanostructures 400 deposited on a substrate 410 by solution-phase processing after the associated solvent (e.g., water and hydrazine) has been allowed to evaporate. In this particular embodiment, the nanostructures 400 are arranged in a substantially disordered (i.e., random) manner.

Copper nanofibers may also be formed by electrospinning In one or more alternative non-limiting embodiments of the present invention, for example, a solution of copper acetate (Cu(OAc)₂ where Ac=(CH₃CO₂)) dissolved in polyvinyl acetate (PVA) is electrospun onto a substrate to form polymer nanofibers comprising copper precursors. The polymer nanofibers are then heated at 500° C. in air for 2 hours in order to remove the polymer components. This acts to convert the nanofibers to copper oxide (CuO) nanofibers. Lastly, the copper oxide nanofibers are reduced into copper nanofibers by annealing in a hydrogen atmosphere at 300° C. for one hour. Notably, heating the polymer nanofibers such that the polymer nanofibers melt somewhat when removing the polymer components can be used to cause the resultant network of copper nanofibers to fuse together at their junctions (i.e., crossing points). This results in a fused network of copper nanofibers with extremely low junction resistances.

FIG. 5A shows a top elevational view of an illustrative network of conductive nanostructures 500 deposited on a substrate 510 by electrospinning Like the network of conductive nanostructures 400 shown in FIG. 4A, in this particular embodiment, the nanostructures are arranged in a substantially disordered (i.e., random) manner. However, in the network of conductive nanostructures 500 shown in FIG. 5A, the nanostructures are fused together at their various junctions.

Lastly, as just one more example, copper nanofibers may also be formed by patterning techniques such as nanoimprint lithography. In one or more additional non-limiting embodiments of the invention, for instance, nanoimprint lithography is utilized to transfer a pattern for the copper nanofibers onto a resist layer on a substrate. The patterned resist/substrate is then exposed to oxygen residual etching, copper metallization, and, finally, resist lift-off.

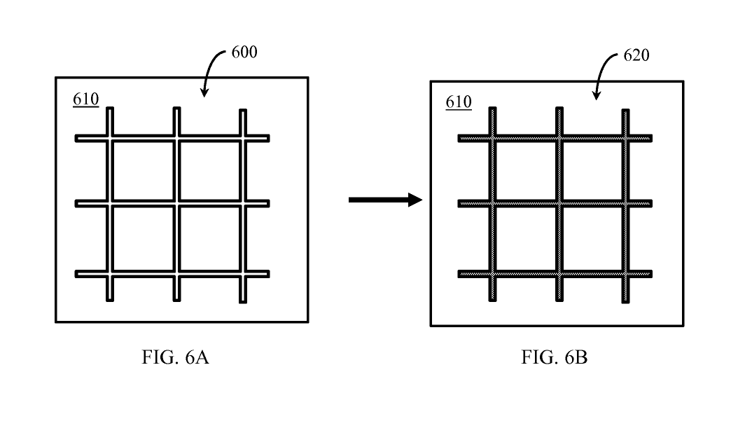

FIG. 6A shows a top elevational view of an illustrative network of conductive nanostructures 600 deposited on a substrate 610 by patterning. Unlike, the networks of conductive nanostructures 400, 500 shown in FIGS. 4A and 5A, in this particular embodiment, the conductive nanostructures 600 are arranged in an ordered manner. More particularly, the network of conductive nanostructures 600 is arranged as a grid. The nanostructures in the network of conductive nanostructures 600, moreover, are fused together at their junctions.

After the deposition of the conductive nanostructures is completed, the method 300 in FIG. 3 advances to step 320. Step 320 comprises depositing a passivating film on the conductive nanostructures to form transparent electrodes. The deposition of the passivating film is preferably accomplished selectively, that is, with little or no deposition occurring on the underlying substrate.

As indicated above, the passivating film comprises one or more layers of graphene. Each of the one or more layers of graphene substantially comprises a respective one-atomic-layer-thick sheet of sp²-hybridized carbon. Graphene can be synthesized by several methods. U.S. Patent Publication No. 2011/0091647, to Colombo et al. and entitled “Graphene Synthesis by Chemical Vapor Deposition,” hereby incorporated by reference herein, for example, teaches the chemical vapor deposition (CVD) of graphene on metal substrates using hydrogen and methane in an otherwise largely conventional CVD tube furnace reactor. In one or more embodiments of the present invention, graphene CVD is performed by loading the network of conductive nanostructures and the substrate formed in step 310 into a CVD tube furnace and introducing hydrogen gas at a rate between 1 to 100 standard cubic centimeters per minute (sccm) while heating the substrate to a temperature between 400° C. and 1,400° C. These conditions are maintained for a duration of time between 0.1 to 60 minutes. Next methane is introduced into the CVD tube furnace at a flow rate between 1 to 5,000 sccm at between 10 mTorr to 780 Torr of pressure while reducing the flow rate of hydrogen gas to less than 10 sccm. Graphene is synthesized on the metal substrate over a period of time between 0.001 to 10 minutes following the introduction of the methane. Deposition of graphene in this manner deposits graphene readily on copper and other metals while depositing little or no graphene on glass or plastic.

The end product of the deposition of the passivating film is a transparent electrode (i.e., a network of passivated nanostructures). FIG. 4B shows a top elevational view of a transparent electrode 420 formed by depositing a passivating film on the disordered network of conductive nanostructures 400. Likewise, FIG. 5B shows a top elevational view of a transparent electrode 520 formed by depositing a passivating film on the disordered and fused network of conductive nanostructures 500. Lastly, FIG. 6B shows a top elevational view of a transparent electrode 620 formed by depositing a passivating film on the ordered and fused network of conductive nanostructures 600.

Transparent electrodes in accordance with aspects of the invention may be used in a wide variety of both rigid and flexible optoelectronic devices including, but not limited to, liquid crystal displays, flat panel displays, touch panels, electronic inks, organic photovoltaic (OPV) devices (i.e., solar cells), and organic light emitting diodes (OLEDs). These optoelectronic devices will be familiar to one of ordinary skill in the optoelectronics art, and are also described in a number of readily available publications including, for example, G. P. Wiederrecht, Handbook of Nanoscale Optics and Electronics, Academic Press, 2010, which is hereby incorporated by reference herein. Exemplary embodiments of two such devices are described below.

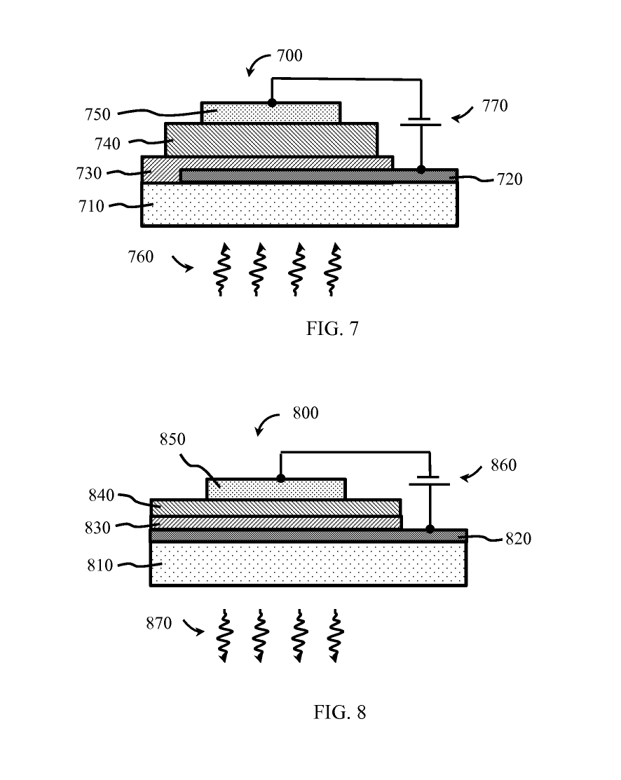

FIG. 7 shows a sectional view of a portion of an OPV device 700 in accordance with an illustrative embodiment of the present invention. This particular embodiment comprises a substrate 710, an anode 720, a buffer layer 730, an active layer 740, and a cathode 750. The anode 720 may comprise a transparent electrode in accordance with aspects of the invention like the transparent electrodes 100, 420, 520, 620. In one or more non-limiting embodiments, the substrate 710 may comprise glass or a translucent polymer (e.g., polyethylene terephthalate). The buffer layer 730 may comprise poly(3,4-ethylenedioxythiophene):poly(styrene sulfonate) (PEDOT:PSS). The active layer 740 may comprise a mixture of poly(3-hexylthiophene) (P3HT) (an electron donor) and the fullerene [6,6]-phenyl-C61 buytric acid methyl ester (PCBM) (an electron acceptor) to create a bulk heterojunction. Finally, the cathode 750 may comprise aluminum.

The buffer layer 730 serves to increase hole-injection efficiencies by increasing the work function of the anode 720. When the OPV device 700 is in operation, light (photons) 760 pass through the substrate 710, the anode 720, and the buffer layer 730, and create holes and electrons in the active layer 740. The holes and electrons, in turn, pass to the anode 720 and to the cathode 750, respectively. An output voltage 770 is thereby created between the anode 720 and the cathode 750.

FIG. 8 shows a sectional view of a portion of an OLED device 800 in accordance with an illustrative embodiment of the invention. The exemplary OLED device 800 comprises a substrate 810, an anode 820, a hole transport layer 830, an electron transport layer 840, and a cathode 850. The anode 820 may again comprise a transparent electrode in accordance with aspects of the invention like the transparent electrodes 100, 420, 520, 620. In one or more non-limiting embodiments, the substrate 810 may comprise glass or a translucent polymer (e.g., polyethylene terephthalate). The hole transport layer 830 may comprise N,N′-diphenyl-N, N′-bis(3-methylphenyl) 1,1′-biphenyl-4,4′ diamine (TPD). The electron transport layer 840 may comprise tris(8-hydroxyquinoline) aluminum (Alq3). Finally, the cathode 850 may comprise aluminum.

When the OLED device 800 is in operation, an input voltage 860 is applied between the anode 820 and the cathode 850 which causes holes and electrons to recombine at the interface of the hole transport layer 830 and the electron transport layer 840. This results in the output of photons 870, which pass through the hole transport layer 830, the anode 820, and the substrate 810, and ultimately out of the OLED device 800.

It should again be emphasized that the above-described embodiments of the invention are intended to be illustrative only. Other embodiments can use different types and arrangements of elements and/or different method steps for implementing the described functionality. These numerous alternative embodiments within the scope of the appended claims will be apparent to one skilled in the art.

Moreover, all the features disclosed herein may be replaced by alternative features serving the same, equivalent, or similar purposes, unless expressly stated otherwise. Thus, unless expressly stated otherwise, each feature disclosed is one example only of a generic series of equivalent or similar features.

Any element in a claim that does not explicitly state “means for” performing a specified function or “step for” performing a specified function is not to be interpreted as a “means for” or “step for” clause as specified in 35 U.S.C. §112, ¶6. In particular, the use of “steps of” in the claims herein is not intended to invoke the provisions of 35 U.S.C. §112, ¶6.

What is claimed is:

1. An electrode for use in an electronic device, the electrode comprising:
a plurality of nanostructures, each nanostructure in the plurality of nanostructures contacting or fused to one or more other nanostructures in the plurality of nanostructures; and
a passivating film, the passivating film at least partially covering the plurality of nanostructures and comprising one or more layers of graphene.

2. The electrode of claim 1, wherein the plurality of nanostructures comprise a metal.

3. The electrode of claim 2, wherein the metal comprises copper.

4. The electrode of claim 1, wherein the plurality of nanostructures comprise nanofibers.

5. The electrode of claim 1, wherein the plurality of nanostructures are substantially disordered.

6. The electrode of claim 1, wherein the plurality of nanostructures are substantially ordered.

7. The electrode of claim 6, wherein the plurality of nanostructures describe a grid.

8. The electrode of claim 1, wherein the passivating film comprises only one layer of graphene.

9. The electrode of claim 1, wherein the passivating film comprises two or more layers of graphene.

10. The electrode of claim 1, wherein the passivating film is deposited by chemical vapor deposition.

11. The electrode of claim 1, wherein the electrode is installed in an optoelectronic device.

12. A method of forming an electrode, the method comprising the steps of:
forming a plurality of nanostructures, each nanostructure in the plurality of nanostructures contacting or fused to one or more other nanostructures in the plurality of nanostructures; and
depositing a passivating film on the plurality of nanostructures, the passivating film comprising one or more layers of graphene.

13. The method of claim 12, wherein the forming step comprises at least one of solution-phase processing, electrospinning, and patterning.

14. The method of claim 12, wherein the forming step comprises forming the plurality of nanostructures on a substrate.

15. The method of claim 14, wherein the depositing step does not substantially deposit the passivating film on the substrate.

16. The method of claim 12, wherein the depositing step comprises chemical vapor deposition.

17. The method of claim 16, wherein the chemical vapor deposition utilizes at least methane and hydrogen.

18. The method of claim 12, further comprising the step of installing a product of the depositing step into an optoelectronic device.
